(19) United States
(12) Patent Application Publication
(10) Pub. No.: US 2023/0062092 A1
(43) Pub. Date: Mar. 2, 2023

(54) Recessed Access Devices And Methods Of Forming A Recessed Access Devices

(71) Applicant: Micron Technology, Inc., Boise, ID (US)

(72) Inventors: Hyuck Soo Yang, Meridian, ID (US); Sau Ha Cheung, Boise, ID (US); Richard Beeler, Boise, ID (US); Ping Chieh Chiang, Boise, ID (US); Hyoung Lee, Boise, ID (US); Jaydip Guha, Boise, ID (US); Soichi Sugiura, Bristow, VA (US)

(73) Assignee: Micron Technology, Inc., Boise, ID (US)

(21) Appl. No.: 17/460,984

(22) Filed: Aug. 30, 2021

(51) Int. Cl. H01L 27/108; H01L 29/51

(52) U.S. Cl. CPC H01L 27/10823; H01L 29/512; H01L 29/517; H01L 27/10876

(57) ABSTRACT

A recessed access device comprises a conductive gate in a trench in semiconductor material. A gate insulator extends along sidewalls and around a bottom of the conductive gate between the conductive gate and the semiconductor material. A pair of source/drain regions are in upper portions of the semiconductor material on opposing lateral sides of the trench. A channel region in the semiconductor material below the pair of source/drain regions extends along sidewalls and around a bottom of the trench. The gate insulator comprises a low-k material and a high-k material. The low-k material is characterized by its dielectric constant k being no greater than 4.0. The high-k material is both (a) and (b), where:
(a): characterized by its dielectric constant k being greater than 4.0; and
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material.
   Other embodiments, including method, are disclosed.

### TECHNICAL FIELD

Embodiments disclosed herein pertain to recessed access devices and to methods of forming recessed access devices.

### BACKGROUND

A recessed access device is a field effect transistor having its gate construction buried within a trench formed in semiconductive material. The gate construction includes a gate insulator which lines the trench and conductive gate material within the trench laterally inward of the gate insulator. A source/drain region is formed in outermost regions of the semiconductive material on each of opposing sides of the trench. When the two source/drain regions are at different voltages and a suitable voltage is applied to the conductive gate material, current (Iₒₙ) flows through the semiconductive material between the source/drain regions along the trench sidewalls and around the base of the trench (i.e., a conductive channel forms through which current flows between the two source/drain regions). Recessed access devices are typically devoid of non-volatile charge-storage devices (yet may be fabricated to include such), and regardless may be used in memory circuitry, for example DRAM circuitry. It is desirable to attain high device on-current (Iₒₙ) and low device off-current (e.g., leakage current I_{off}) in recessed access devices.

### BRIEF DESCRIPTION OF THE DRAWINGS

FIG. 1 is a diagrammatic cross-sectional view of multiple recessed access devices in DRAM in accordance with an embodiment of the invention.

FIG. 2 is an enlarged view of a portion of FIG. 1.

FIGS. 3-10 are diagrammatic cross-sectional views of one or more recessed access device(s) in accordance with embodiments of the invention.

FIGS. 11-18 show example methods of forming a recessed access device in accordance with embodiments of the invention.

FIG. 19 is a diagrammatic schematic and structural view of DRAM circuitry in accordance with an embodiment of the invention.

### DETAILED DESCRIPTION OF EXAMPLE EMBODIMENTS

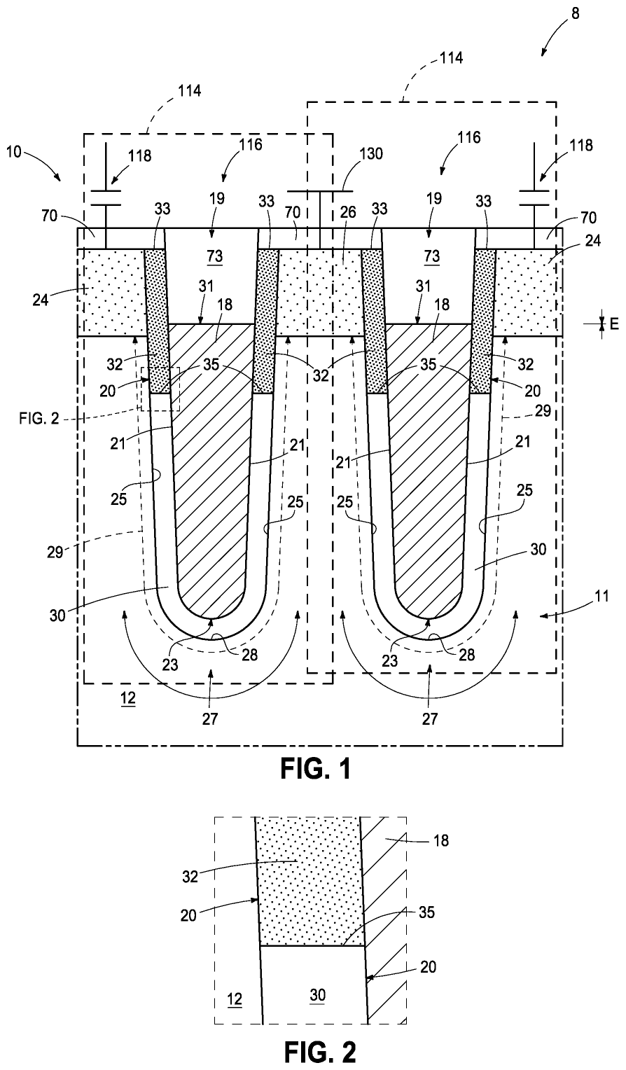

Embodiments of the invention encompass recessed access devices, for example as might be in DRAM constructions, and methods of forming recessed access devices. First example embodiments are initially described with reference to FIGS. 1 and 2 which show an example fragment of a substrate construction 8 comprising a memory array or memory array area 10 that in one embodiment comprises memory cells 114 individually comprising a recessed access device/transistor 116 and a charge-storage device 118 (e.g., a capacitor). Memory cells 114 have been fabricated relative to a base substrate 11. Base substrate 11 may comprise any one or more of conductive/conductor/conducting (i.e., electrically herein), semiconductive/semiconductor/semiconducting, and insulative/insulator/insulating (i.e., electrically herein) materials. Materials may be aside, elevationally inward, or elevationally outward of the FIGS. 1-2-depicted materials. For example, other partially or wholly fabricated components of integrated circuitry may be provided somewhere above, about, or within base substrate 11. Control and/or other peripheral circuitry for operating components within a memory array may also be fabricated, and may or may not be wholly or partially within a memory array or sub-array. Further, multiple sub-arrays may also be fabricated and operated independently, in tandem, or otherwise relative one another. As used in this document, a “sub-array” may also be considered as an array.

Example base substrate 11 comprises semiconductor material 12 (e.g., appropriately and variously doped monocrystalline silicon and/or other semiconductive material) comprising a pair of recessed access devices 116. FIGS. 1 and 2 show recessed access devices 116 as part of memory circuitry although recessed access devices in accordance with the invention might be in any integrated circuitry. The discussion largely proceeds with respect to a single recessed access device 116. Such comprises a conductive gate 18 (e.g., a buried access line) in a trench 19 in semiconductor material 12. In one embodiment, conductive gate 18 consists essentially of or consists of metal material. Example conductive gate 18 has a top 31 that may be planar (as shown). An insulator material 73 (e.g., silicon dioxide, silicon nitride, a material having a dielectric constant k no greater than 4.0, or a material having a dielectric constant k greater than 4.0 may be over conductive gate 18. An insulator material 70 (e.g., silicon dioxide and/or silicon nitride) may be over semiconductor material 12. A gate insulator 20 extends along sidewalls 21 and around a bottom 23 of conductive gate 18 between conductive gate 18 and semiconductor material 12.

A pair of source/drain regions 24, 26 are in upper portions of semiconductor material 12 on opposing lateral sides of trench 19. Each of source/drain regions 24, 26 likely comprises at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁹ atoms/cm³). Accordingly, all or only a part of each source/drain region 24, 26 may have such maximum concentration of conductivity-increasing dopant (indicated by stippling). Source/drain regions 24 and/or 26 may include other doped regions (not shown), for example halo regions, LDD regions, etc.

In the depicted example, one of the source/drain regions (e.g., region 26) of the pair of source/drain regions is laterally between conductive gates 18 and is shared by immediately-adjacent recessed access devices 116. Others of the source/drain regions (e.g., regions 24) of individual of the pairs of source/drain regions are not shared by immediately-adjacent recessed access devices 116. A digitline 130 is directly electrically coupled to the one shared source/drain region 26. A pair of capacitors 118 individually are directly electrically coupled to one of the other source/drain regions 24.

Example recessed access devices 116 comprise a channel region 27 that is in the semiconductor material 12 below the pair of source/drain regions 24, 26 and extends along sidewalls 25 and around a bottom 28 of trench 19. Channel region 27 may be suitably doped with a conductivity-increasing dopant likely of the opposite conductivity-type of the dopant in source/drain regions 24, 26, and for example that is at a maximum concentration in the channel of no greater than 1×10¹⁶ atoms/cm³. When suitable voltage is applied to conductive gate 18, a conductive channel forms (e.g., along a channel current-flow line/path 29) within channel region 27 proximate gate insulator 20 such that current can flow between pair of source/drain regions 24 and 26.

In one embodiment, gate insulator 20 comprises a low-k material 30 (in some embodiments referred to as low-k gate-insulator material) and a high-k material 32 (in some embodiments referred to as high-k gate-insulator material). Low-k material 30 is characterized by its dielectric constant k being no greater than 4.0 (e.g., no less than 0.5). In one embodiment, low-k material comprises at least one of SiO₂ and SiₐO_{b}N_{c}, and in one such embodiment where the at least one of the SiO₂ and SiₐO_{b}N_{c} is carbon-doped (e.g., from 0.01 to 10.0 atomic percent).

In one embodiment, high-k material 32 is both (a) and (b), where:
(a): characterized by its dielectric constant k being greater than 4.0; and
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material.
   The SiₓM_{y}O may be stoichiometric or non-stoichiometric, for example being predominantly stoichiometric or predominantly non-stoichiometric. High-k material 32 may comprise some SiOₓ (that may or may not be stoichiometric) but in sufficiently low concentration that high-k material 32 overall has its dielectric constant k greater than 4.0.

In one embodiment, “x” is 0.999 to 0.96 and “y” is 0.001 to 0.04. In one embodiment, “M” comprises Al. In one embodiment, “M” comprises at least one of La, Lu, Yb, Er, Dy, Gd, Pr, Y, Hf, Zr, Mg, Sr, and Ti. In one embodiment, “M” is only one metal from Group 2, Group 3, Group 4, Group 5, and the lanthanide series of the periodic table, and in one such embodiment “M” is from the lanthanide series. Alternately, “M” is more than one metal from Group 2, Group 3, Group 4, Group 5, and the lanthanide series of the periodic table.

In one embodiment, low-k material 30 has its dielectric constant k at 3.0 to 4.0 and high-k material 32 has its dielectric constant k at 10.0 to 40.0. In one embodiment, low-k material 30 is devoid of SiₓM_{y}O (no detectable SiₓM_{y}O therein). In another embodiment, low-k material 30 comprises SiₓM_{y}O, for example as described in example embodiments below. In one embodiment, high-k material 32 has its top 33 above top 31 of conductive gate 18. In one embodiment, low-k material 30 has its top 35 below top 31 of conductive gate 18.

Any other attribute(s) or aspect(s) as shown and/or described herein with respect to other embodiments may be used in the embodiments shown and described with reference to the above embodiments.

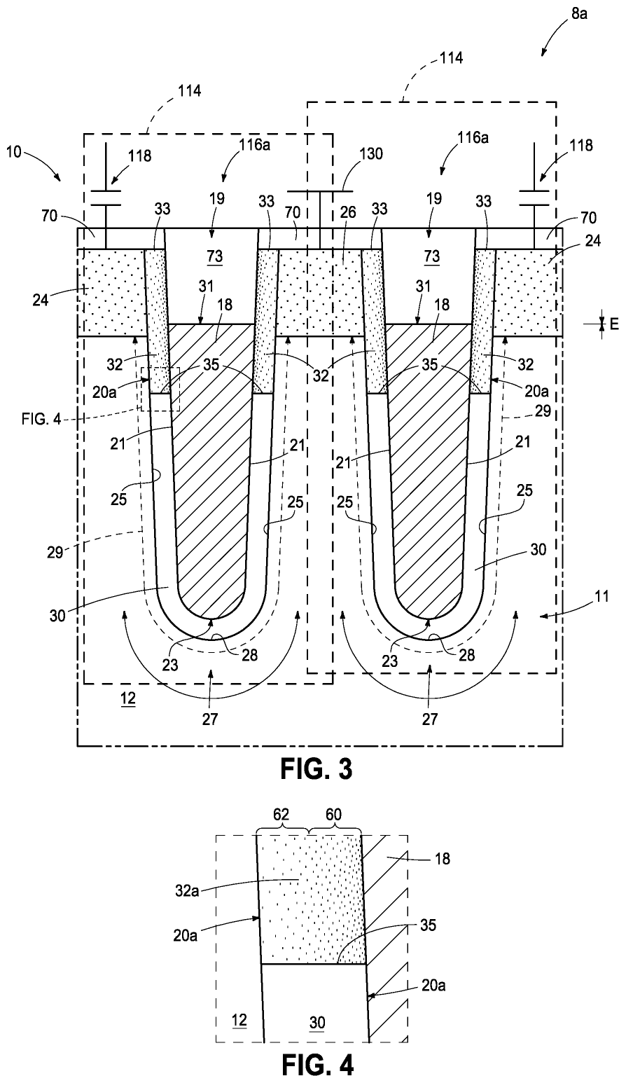

High-k material 32 may be homogenous or non-homogenous (as may be low-k material 20). FIGS. 1 and 2 are intended to show homogeneity of high-k material 32 by constant size and density of stippling horizontally all there-across and vertically there-within. An alternate example embodiment construction 8a comprising a pair of recessed access devices 116a is shown in FIGS. 3 and 4. Like numerals from the above-described embodiments have been used where appropriate, with some construction differences being indicated with the suffix “a” or with different numerals. Example high-k material 32a of gate insulator 20a has varied concentration “M” laterally there-across as intended to be indicated by varied-density stippling, with greater density stippling indicating higher atomic concentration of “M” as compared to lower density stippling. By way of example, a decreasing concentration gradient of “M” (a gradient that may or may not be constant) is shown from the direction of conductive gate 18 to the direction of channel region 27. In one embodiment, high-k material 32a may be considered as comprising a laterally-inner portion 60 and a laterally-outer portion 62 (FIG. 4), with laterally-inner portion 60 having greater quantity of “M” than laterally-outer portion 62. In one such embodiment and as shown, laterally-inner portion 60 and laterally-outer portion 62 each have a decreasing concentration gradient of “M” laterally there-across from direction of conductive gate 18 to direction of channel region 27. In one embodiment, non-homogeneity may also exist vertically within material 32a (not shown by stippling). Any other attribute(s) or aspect(s) as shown and/or described herein with respect to other embodiments may be used.

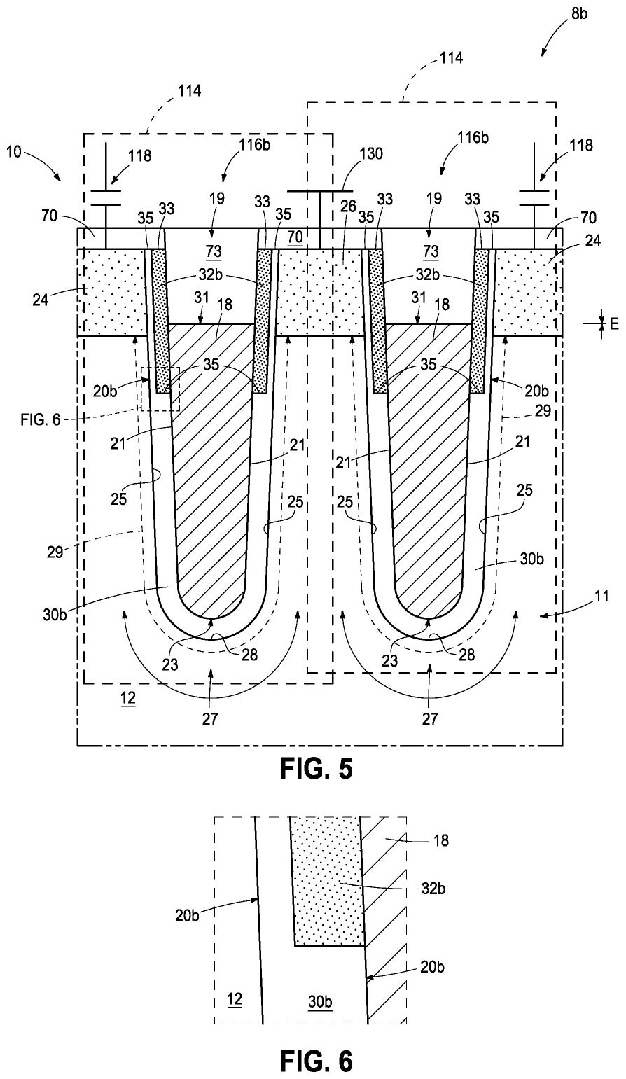

In one embodiment, the high-k material is both aside the low-k material laterally-inward thereof and above the low-k material. One such example embodiment construction 8b comprising a pair of recessed access devices 116b is shown in FIGS. 5 and 6. Like numerals from the above-described embodiments have been used where appropriate, with some construction differences being indicated with the suffix “b” or with different numerals. In gate insulator 20b, high-k material 32b is aside low-k material 30b as well as above low-k material 30b. In one embodiment and as shown, low-k material 30 extends completely along all of sidewalls 21 of and directly under bottom 23 of conductive gate 18. Where the high-k material is located aside the low-k material, such high-k material may be laterally-thicker or laterally-thinner than the low-k material (laterally thicker being shown with respect to high-k material 32b and low-k material 30b). Alternately, the high-k material and the low-k material in such location may have the same lateral thickness (not shown). Regardless, high-k material 32b may be homogenous or non-homogenous. Any other attribute(s) or aspect(s) as shown and/or described herein with respect to other embodiments may be used.

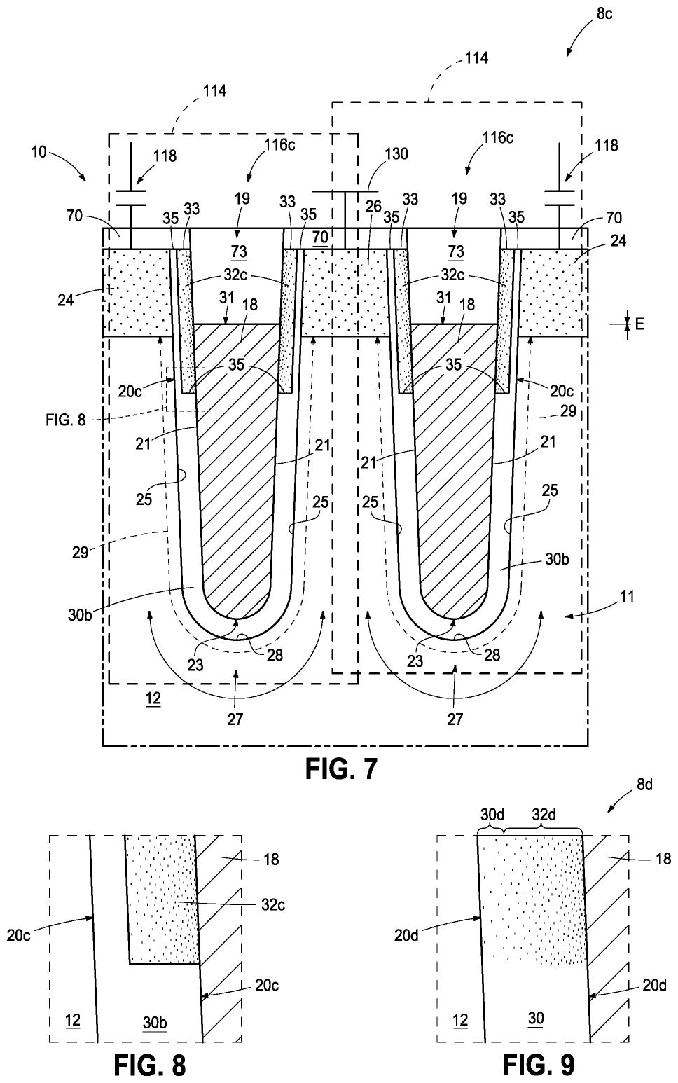

An alternate example embodiment construction 8c comprising a pair of recessed access devices 116c is shown in FIGS. 7 and 8. Like numerals from the above-described embodiments have been used where appropriate, with some construction differences being indicated with the suffix “c” or with different numerals. Example high-k material 32c of gate insulator 20c has varied concentration “M” laterally there-across (it is not homogenous). Any other attribute(s) or aspect(s) as shown and/or described herein with respect to other embodiments may be used.

The embodiments of FIGS. 1-4 may be considered as embodiments where the high-k material is not aside the low-k material. Alternately, the embodiment of FIGS. 3 and 4 may comprise an embodiment where the high-k material is aside the low-k material as exemplified in a construction 8d in FIG. 9 corresponding to that of FIG. 4. Like numerals from the above-described embodiments have been used where appropriate, with some construction differences being indicated with the suffix “d” or with different numerals. Example construction 8d in FIG. 9 is shown as being the same as construction 8a in FIG. 4 but for designation of a low-k material 30d aside a high-k material 32d as part of gate insulator 20d. Such may occur where concentration of “M” in SiₓM_{y}O, is sufficiently low where such becomes/is low-k (i.e., it has its dielectric constant k being no greater than 4.0; e.g., no less than 0.5). Thereby, and in one such embodiment, the low-k material comprises the SiₓM_{y}O, but where its dielectric constant k is 4.0 or less. Any other attribute(s) or aspect(s) as shown and/or described herein with respect to other embodiments may be used.

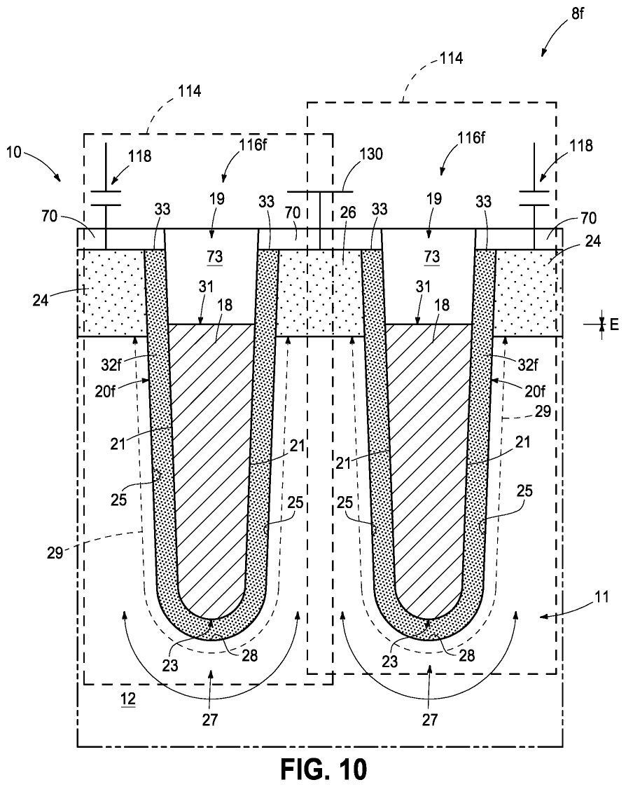

An alternate example embodiment construction 8f comprising a pair of recessed access devices 116f is shown in FIG. 10. Like numerals from the above-described embodiments have been used where appropriate, with some construction differences being indicated with the suffix “f” or with different numerals. In construction 8f, regardless of any presence of a low-k material (no low-k material 30 being shown), gate insulator 20f comprises high-k material 32f that is all of (a), (b), and (c), where:
(a): characterized by its dielectric constant k being greater than 4.0;
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material.
(c): having its top 33 above top 31 of conductive gate 18.
   Any other attribute(s) or aspect(s) as shown and/or described herein with respect to other embodiments may be used.

A possible, although not required, advantage of some embodiments of the invention over some constructions of the prior art is reduction of a phenomenon known as gate-induced-drain-leakage (GIDL) at an LDD junction when such a junction is present. Such reduced GIDL may enable use of an all-metal-material gate 18 as opposed to conductive polysilicon-over-metal material of some prior art gate constructions which may thereby increase conductivity (reduce resistance) of gate 18.

Embodiments of the invention encompass methods of forming a recessed access device. Embodiments of the invention encompass a recessed access device independent of method of manufacture. Nevertheless, such recessed access device may have any of the attributes as described herein in method embodiments. Likewise, the described method embodiments may incorporate, form, and/or have any of the attributes described with respect to structure embodiments.

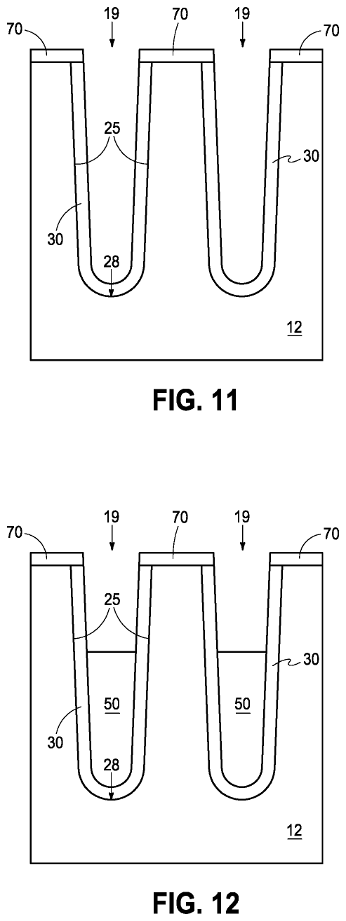

An example embodiment of a method of forming a recessed access device in accordance with the invention is first described with reference to FIGS. 11-15. Referring to FIG. 11, a trench 19 has been formed in semiconductor material 12 (e.g., by photolithography and etch). Insulator material 70 may be over semiconductor material 12 and if so trench 19 may also be formed there-through. Silicon-containing low-k gate-insulator material 30 has been formed over sidewalls 25 and bottom 28 of trench 19, with silicon-containing low-k gate-insulator material 30 being characterized by its dielectric constant k being no greater than 4.0. In one embodiment, semiconductor material 12 comprises silicon and forming silicon-containing low-k gate-insulator material 30 comprises oxidizing such silicon to form SiO₂ (e.g., by in situ steam generation). In one such embodiment, a layer (not shown) of SiO₂ may be atomic-layer-deposited over trench sidewalls 25 and trench bottom 28 prior to such oxidizing. Regardless, sidewalls 25 and bottom 28 may move laterally-out and down, respectively, during such oxidizing due to transformation of material 12 to material 30 by such oxidizing.

A lining is formed in the trench laterally-inward of the low-k gate-insulator material, with the lining comprising at least one of elemental-form M, alloy-form M, and a metal oxide (regardless of whether stoichiometric), where M or the metal of the metal oxide is one or more of Al, metal(s) from Group 2, Group 3, Group 4, Group 5, and the lanthanide series of the periodic table. In one embodiment, the lining comprises at least one of elemental-form M and alloy-form M, in one embodiment comprises the metal oxide, and in one embodiment comprises at least one of elemental-form M and alloy-form M and comprises the metal oxide.

In one embodiment, the lining is directly against some and only some of the low-k gate-insulator material that is in the trench. For example, and by way of example only, FIG. 12 shows forming of sacrificial material 50 in a bottom portion of trench 19 over low-k gate-insulator material 30 and over trench bottom 28. Such may comprise any suitable conductive, insulative, and/or semiconductive material, with TiN being but one example. Such may be formed by overfilling remaining volume of trench 19 from FIG. 11, followed by etching such back from being received laterally-outward of and above trench 19. In one embodiment and as shown, sacrificial material 50 has been formed to fill more than half of the remaining volume of trench 19 after lining sidewalls 25 and bottom 28 thereof with low-k gate-insulator material 30, for example where it is desired that the ultimate high-k gate-insulator material to be formed be over less than 50% of the sidewalls of the conductive gate to-be-formed.

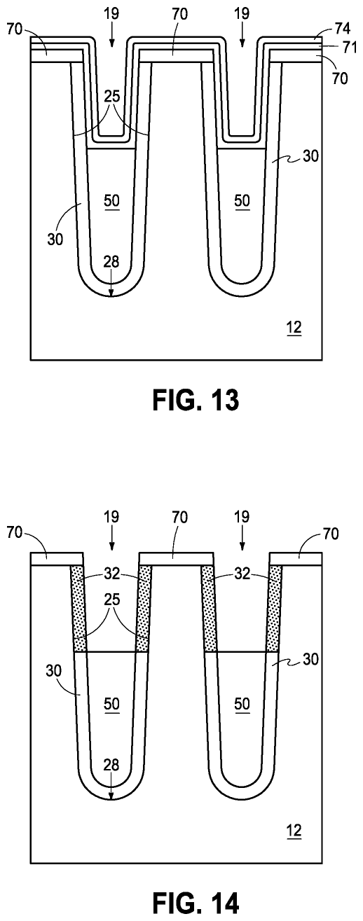

Referring to FIG. 13, a lining 71 has been formed in an upper portion of trench 19 above sacrificial material 50 and laterally-inward of low-k gate-insulator material 30 that is in the upper portion of trench 19. Lining 71 comprises the at least one of elemental-form M, alloy-form M, and a metal oxide as referred to above. In one embodiment, lining 71 is thinner than low-k gate-insulator material 30. In one embodiment, lining 71 is formed directly against low-k gate-insulator material 30 and directly against sacrificial material 50. In one embodiment and as shown, lining 71 has been formed to completely cover a top 51 of sacrificial material 50. Alternately, and by way of example only, such may not be so formed, for example by using a deposition technique for forming lining 71 in a manner that is highly selective to deposit on (directly against) low-k gate-insulator material 30 relative to sacrificial material 50 (not shown). In one embodiment and as shown, sacrifice/sacrificial material 74 (e.g., TiN) has been formed to cover lining 71.

Referring to FIG. 14, material of the lining 71 has been reacted with low-k gate-insulator material 30 to form high-k gate-insulator material 32 comprising SiₓM_{y}O, where “x” is 0.999 to 0.6 and “y” is 0.001 to 0.4, with high-k gate-insulator material 32 being characterized by its dielectric constant k being greater than 4.0. Remaining portions of lining 71 and sacrifice material 74 (not shown) have then been removed. In one embodiment, the reacting comprises annealing (e.g., by furnace anneal at a temperature of at least 400° C. or by rapid-thermal-processing). Alternately, incident radiation of suitable quanta capable of imparting the stated reacting may be used without necessarily raising temperature of lining 71 and low-k gate-insulator 30 to cause the reacting by thermal means. In one embodiment and as shown, sacrifice material 74 (not shown in FIG. 14) has been formed prior to and that covers lining 71 during annealing. Such may facilitate or prevent material of lining 71 from outgassing during such annealing. Regardless, those of skill in the art are capable of selecting suitable quanta of energy for such reacting to achieve a desired construction and composition for the high-k gate-insulator material to achieve, for example, any of compositions/constructions 32, 32a, 32b, 32c, or 32d as shown in FIGS. 1-10.

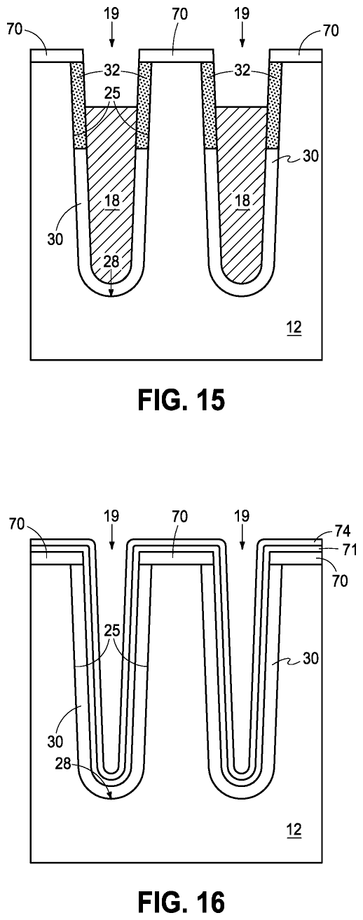

Referring to FIG. 15, sacrificial material 50 (not shown) has been replaced with conductive gate 18 after the reacting. For example, sacrificial material 50 may be removed from trench 19 by isotropic etching and thereafter filling remaining volume of trench 19 with conductive material and removing such back to have an example construction as shown. Regardless, and as shown in FIG. 1, in an example method, a pair of source/drain regions 24, 26 is formed in upper portions of semiconductor material 12 on opposing lateral sides of trench 19. Further, a channel region 27 is in semiconductor material 12 below the pair of source/drain regions and extends along trench sidewalls 25 and around trench bottom 28.

Any other attribute(s) or aspect(s) as shown and/or described herein with respect to other embodiments may be used.

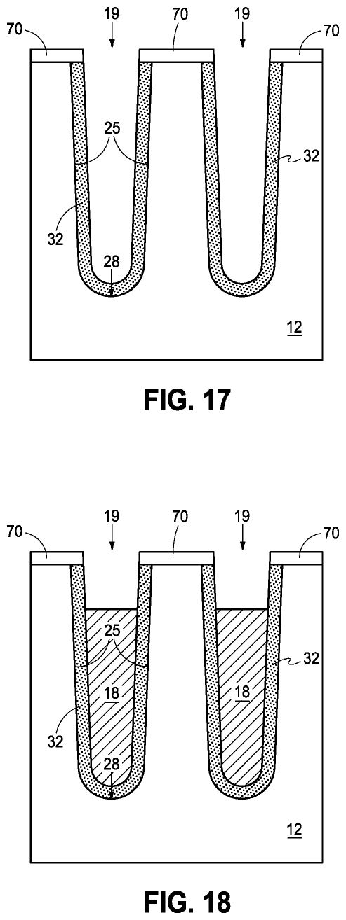

FIGS. 11-15 show an example embodiment where lining 71 is formed to be directly against some and only some of low-k gate-insulator material 30 that is in trench 19 and thereby high-k gate-insulator material 32 is formed along some and only some of the trench sidewalls 25 or along some and only some of trench bottom 28. As an alternate example, the lining may be formed to be directly against all of the low-k gate-insulator material that is in the trench and thereby the high-k gate-insulator material is formed along all of the trench sidewalls and along all of the trench bottom. For example, FIG. 16 shows and example construction where lining 71 has been formed to be directly against all of low-k gate-insulator material 30 that is in trench 19. FIGS. 17 and 18 show analogous processing to that described above for FIGS. 14 and 15, respectively.

Any other attribute(s) or aspect(s) as shown and/or described herein with respect to other embodiments may be used.

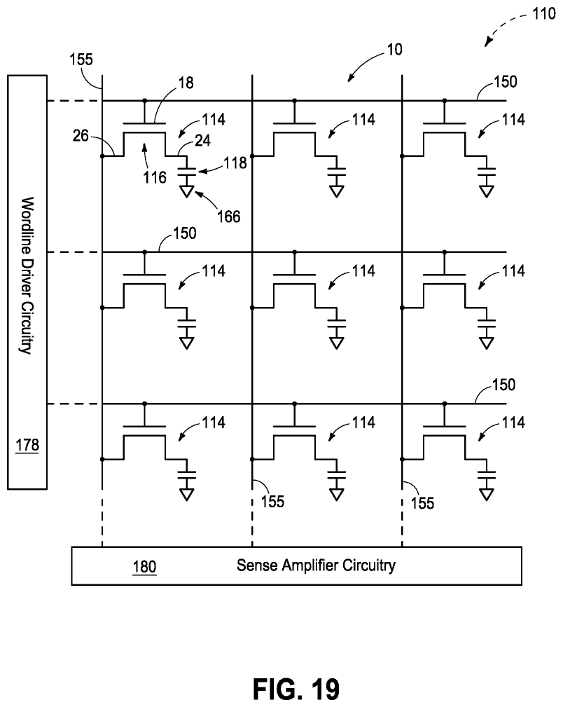

FIG. 19 diagrammatically and schematically illustrates a portion of DRAM circuitry 110 in accordance with an aspect of the invention in which a recessed access device 116 comprises a part thereof. Like numerals from the above-described embodiments are used. Circuitry 110 comprises a memory array 10 comprising memory cells 114 individually comprising a recessed access device 116 and a charge-storage device 118. Transistors 116 individually comprise two source/drain regions 24, 26 having a gate 18 there-between that is part of one of multiple wordlines 150 of memory array 10. One of the source/drain regions (e.g., 24) is electrically coupled (e.g., directly electrically coupled) to one of charge-storage devices 118. The other of the source/drain regions (e.g., 26) is electrically coupled to one of multiple sense lines 155 of memory array 10. Example charge-storage devices 118 as a capacitor has one of its nodes directly electrically coupled to source/drain region 24 of a recessed access device transistor 116 and another node directly electrically coupled to a cell plate 166. Example cell plate 166 may be at any suitable reference voltage, including by way of example, 0V, a power supply voltage Vcc, one half of Vcc, or the like, depending upon application. DRAM circuitry 110 comprises peripheral circuitry comprising, for example, wordline-driver circuitry 178 and sense-line-amplifier circuitry 180. Wordlines 150 extend from memory array 10 to wordline-driver circuitry 178 and sense lines 155 extend from memory array 10 to sense-line-amplifier circuitry 180. By way of example, the peripheral circuitry may be wholly laterally aside memory array 10. Such may be partially laterally aside memory array 10 and/or wholly or partially above or below memory array 10. Regardless, additional peripheral circuitry may be provided (not shown). Wordlines 150 and sense lines 155 individually comprise one or more conductive materials (e.g., metal material) and that may not be the same relative one another.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be metal material and/or conductively-doped semiconductive/semiconductor/semiconducting material. “Metal material” is any one or combination of an elemental metal, any mixture or alloy of two or more elemental metals, and any one or more conductive metal compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a recessed access device comprises a conductive gate in a trench in semiconductor material. A gate insulator extends along sidewalls and around a bottom of the conductive gate between the conductive gate and the semiconductor material. A pair of source/drain regions are in upper portions of the semiconductor material on opposing lateral sides of the trench. A channel region in the semiconductor material below the pair of source/drain regions extends along sidewalls and around a bottom of the trench. The gate insulator comprises a low-k material and a high-k material. The low-k material is characterized by its dielectric constant k being no greater than 4.0. The high-k material is both (a) and (b), where:
(a): characterized by its dielectric constant k being greater than 4.0; and
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material.

In some embodiments, a recessed access device comprises a conductive gate in a trench in semiconductor material. A gate insulator extends along sidewalls and around a bottom of the conductive gate between the conductive gate and the semiconductor material. A pair of source/drain regions are in upper portions of the semiconductor material on opposing lateral sides of the trench. A channel region in the semiconductor material below the pair of source/drain regions extends along sidewalls and around a bottom of the trench. The gate insulator comprises a high-k material. The high-k material is all of (a), (b), and (c), where:
(a): characterized by its dielectric constant k being greater than 4.0;
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material;
(c): having its top above a top of the conductive gate.

In some embodiments, a method of forming a recessed access device comprises forming a trench in semiconductor material. Silicon-containing low-k gate-insulator material is formed over sidewalls and a bottom of the trench. The silicon-containing low-k gate-insulator material is characterized by its dielectric constant k being no greater than 4.0. A lining is formed in the trench laterally-inward of the low-k gate-insulator material. The lining comprises at least one of elemental-form M, alloy-form M, and a metal oxide where M or the metal of the metal oxide is one or more of Al, metal(s) from Group 2, Group 3, Group 4, Group 5, and the lanthanide series of the periodic table. Material of the lining is reacted with the low-k gate-insulator material to form high-k gate-insulator material comprising SiₓM_{y}O, where “x” is 0.999 to 0.6 and “y” is 0.001 to 0.4. The high-k gate-insulator material is characterized by its dielectric constant k being greater than 4.0. A conductive gate is formed in the trench over sidewalls of the high-k gate-insulator material. A pair of source/drain regions are formed in upper portions of the semiconductor material on opposing lateral sides of the trench. A channel region is in the semiconductor material below the pair of source/drain regions and extends along the trench sidewalls and around the trench bottom.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A recessed access device comprising:
a conductive gate in a trench in semiconductor material;
a gate insulator extending along sidewalls and around a bottom of the conductive gate between the conductive gate and the semiconductor material;
a pair of source/drain regions in upper portions of the semiconductor material on opposing lateral sides of the trench;
a channel region in the semiconductor material below the pair of source/drain regions extending along sidewalls and around a bottom of the trench; and
the gate insulator comprising a low-k material and a high-k material, the low-k material being characterized by its dielectric constant k being no greater than 4.0, the high-k material being both (a) and (b), where:
(a): characterized by its dielectric constant k being greater than 4.0; and
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material.

2. The recessed access device of claim 1 wherein “x” is 0.999 to 0.96, and “y” is 0.001 to 0.04.

3. The recessed access device of claim 1 wherein “M” comprises at least one of La, Lu, Yb, Er, Dy, Gd, Pr, Y, Hf, Zr, Mg, Sr, and Ti.

4. The recessed access device of claim 1 wherein “M” comprises Al.

5. The recessed access device of claim 1 wherein “M” is only one metal from Group 2, Group 3, Group 4, Group 5, and the lanthanide series of the periodic table.

6. The recessed access device of claim 5 wherein “M” is from the lanthanide series.

7. The recessed access device of claim 1 wherein “M” is more than one metal from Group 2, Group 3, Group 4, Group 5, and the lanthanide series of the periodic table.

8. The recessed access device of claim 1 wherein the high-k material is homogenous.

9. The recessed access device of claim 1 wherein the high-k material is not homogenous.

10. The recessed access device of claim 9 wherein the high-k material comprises a laterally-inner portion and a laterally-outer portion, the laterally-inner portion having greater quantity of “M” than the laterally-outer portion.

11. The recessed access device of claim 10 wherein the laterally-inner portion and the laterally-outer portion each have a decreasing concentration gradient of “M” laterally there-across from direction of the conductive gate to direction of the channel region.

12. The recessed access device of claim 9 wherein the high-k material is not homogenous both vertically and laterally.

13. The recessed access device of claim 1 wherein the high-k material is both aside the low-k material laterally-inward thereof and above the low-k material.

14. The recessed access device of claim 13 wherein, where the high-k material is located aside the low-k material, the high-k material is laterally-thicker than the low-k material.

15. The recessed access device of claim 13 wherein, where the high-k material is located aside the low-k material, the low-k material is laterally-thicker than the high material.

16. The recessed access device of claim 13 wherein, where the high-k material is located aside the low-k material, the high-k material and the low-k material have a same lateral thickness.

17. The recessed access device of claim 13 wherein, where the low-k material is located aside the high-k material, the low-k material comprises the SiₓM_{y}O.

18. The recessed access device of claim 1 wherein the high-k material is not aside the low-k material.

19. The recessed access device of claim 1 wherein the low-k material is devoid of the SiₓM_{y}O.

20. The recessed access device of claim 1 wherein the low-k material comprises the SiₓM_{y}O.

21. The recessed access device of claim 1 wherein the low-k material comprises at least one of SiO₂ and SiₐO_{b}N_{c}.

22. The recessed access device of claim 21 wherein the at least one of the SiO₂ and SiₐO_{b}N_{c} is carbon-doped.

23. The recessed access device of claim 1 wherein the high-k material has its top above a top of the conductive gate.

24. The recessed access device of claim 1 wherein the low-k material has its top below a top of the conductive gate.

25. The recessed access device of claim 1 wherein,
the high-k material has its top above a top of the conductive gate; and
the low-k material has its top below the top of the conductive gate.

26. The recessed access device of claim 1 wherein the k material extends completely along all of the sidewalls of the conductive gate and directly under the bottom of the conductive gate.

27. The recessed access device of claim 1 wherein the conductive gate consists essentially of or consists of metal material.

28. DRAM circuitry comprising multiple memory cells individually comprising the recessed access device of claim 1.

29. A recessed access device comprising:
a conductive gate in a trench in semiconductor material;
a gate insulator extending along sidewalls and around a bottom of the conductive gate between the conductive gate and the semiconductor material;
a pair of source/drain regions in upper portions of the semiconductor material on opposing lateral sides of the trench;
a channel region in the semiconductor material below the pair of source/drain regions extending along sidewalls and around a bottom of the trench; and
the gate insulator comprising a high-k material, the high-k material being all of (a), (b), and (c), where:
(a): characterized by its dielectric constant k being greater than 4.0;
(b): comprising SiₓM_{y}O, where “M” is one or more of Al, metal(s) from Group 2, Group 3, Group 4, Group 5, and the lanthanide series of the periodic table; “x” is 0.999 to 0.6; and “y” is 0.001 to 0.4; the SiₓM_{y}O being above the low-k material;
(c): having its top above a top of the conductive gate.

30-35. (canceled)

36. A method of forming a recessed access device, comprising:
forming a trench in semiconductor material;
forming silicon-containing low-k gate-insulator material over sidewalls and a bottom of the trench, the silicon-containing low-k gate-insulator material being characterized by its dielectric constant k being no greater than 4.0;
forming a lining in the trench laterally-inward of the low-k gate-insulator material, the lining comprising at least one of elemental-form M, alloy-form M, and a metal oxide where M or the metal of the metal oxide is one or more of Al, metal(s) from Group 2, Group 3, Group 4, Group 5, and the lanthanide series of the periodic table;
reacting material of the lining with the low-k gate-insulator material to form high-k gate-insulator material comprising SiₓM_{y}O, where “x” is 0.999 to 0.6 and “y” is 0.001 to 0.4, the high-k gate-insulator material being characterized by its dielectric constant k being greater than 4.0;
forming a conductive gate in the trench over sidewalls of the high-k gate-insulator material;
forming a pair of source/drain regions in upper portions of the semiconductor material on opposing lateral sides of the trench; and
a channel region being in the semiconductor material below the pair of source/drain regions and extending along the trench sidewalls and around the trench bottom.

37-57. (canceled)
